(19) United States
(12) Patent Application Publication
(10) Pub. No.: US 2025/0089374 A1
(43) Pub. Date: Mar. 13, 2025

(54) Display Panel and Display Device Including the Same

(71) Applicant: LG Display Co., Ltd., Seoul (KR)

(72) Inventors: Chang Bae Park, Paju-si (KR); Seong Hwan Ju, Paju-si (KR); Seok Ho Shim, Paju-si (KR); Hyun Woo Kim, Paju-si (KR)

(21) Appl. No.: 18/807,759

(22) Filed: Aug. 16, 2024

(30) Foreign Application Priority Data
Sep. 11, 2023 (KR) 10-2023-0120514

(51) Int. Cl. H01L 27/12; H01L 25/16

(52) U.S. Cl. CPC H10D 86/60; H01L 25/167; H10D 86/441

(57) ABSTRACT

A display panel presented herein includes: a plurality of pixel areas including a plurality of pixels; and a gate driving area including a plurality of gate driving circuits that supply a gate signal to a plurality of gate lines connected to the plurality of pixels. The gate driving area is between adjacent pixel areas of the plurality of pixel areas. A length of a row direction of each sub-pixels of a first color is greater than a length of a row direction of each of sub-pixels of second and third colors.

### CROSS-REFERENCE TO RELATED APPLICATION

This application claims the priority from Republic of Korea Patent Application No. 10-2023-0120514, filed on Sep. 11, 2023, which is hereby incorporated by reference in its entirety.

### BACKGROUND

### Field

The present disclosure relates to a display panel and a display device including the same.

### Description of Related Art

Organic light emitting display devices reproduce images by emitting light using an organic light emitting diode (OLED) placed in each pixel according to an input image signal. The organic light emitting display devices have a fast response speed and high luminous efficiency, luminance, and viewing angle, and have an excellent contrast ratio and color reproducibility as it can express black grayscales in full black. No backlight unit is required for these organic light emitting display devices.

In recent years, the display devices that use a light emitting diode (LED), which is an inorganic light-emitting device, as the light-emitting element of pixels have attracted attention as the next generation of the display devices. Because the LEDs are made of inorganic materials, they don't require a separate encapsulation layer to protect the organic material from moisture, and they have an excellent reliability and a longer life than the OLEDs. The LEDs also have a fast light-up speed, excellent luminous efficiency, and are resistant to impact.

The description provided in the background section should not be assumed to be prior art merely because it is mentioned in or associated with the background section. The background section may include information that describes one or more embodiments of the subject technology.

### SUMMARY

The problem addressed by the present disclosure is to provide a display panel and a display device including the display panel in which the dark point may be easily improved and a gate driving circuit area may be secured on the display panel.

The objects of the present disclosure are not limited to the above-mentioned objects, and other objects, which are not mentioned herein, will obviously be understood by those skilled in the art from the following description.

A display panel according to one or more embodiments of the present disclosure includes: a plurality of pixel areas including a plurality of pixels; and a gate driving area including a plurality of gate driving circuits that supply a gate signal to a plurality of gate lines connected to the plurality of pixels. The gate driving area is between adjacent pixel areas of the plurality of pixel areas. Each of the plurality of pixels includes: a first sub-pixel of a first color; a second sub-pixel of the first color that is adjacent to the first sub-pixel of the first color in a column direction of the display panel; a first sub-pixel of a second color; a second sub-pixel of the second color that is adjacent to the first sub-pixel of the second color in the column direction of the display panel; a first sub-pixel of a third color; and a second sub-pixel of the third color that is adjacent to the first sub-pixel of the third color in the column direction of the display panel. A length of a row direction of each of the first sub-pixel of the first color and the second sub-pixel of the first color is greater than a length of a row direction of each of the first sub-pixel of the second color, the second sub-pixel of the second color, the first sub-pixel of the third color, and the second sub-pixel of the third color.

The first color may red. The second color may be green. The third color may be blue.

Each of the first sub-pixel of the first color, the second sub-pixel of the first color, the first sub-pixel of the second color, the second sub-pixel of the second color, the first sub-pixel of the third color, and the second sub-pixel of the third color may include a driving element configured to supply current to a light-emitting element; and a capacitor connected to the driving element. The capacitors in the sub-pixels of the first color may be larger than the capacitors in the sub-pixels of the second and third colors.

The light-emitting elements in the sub-pixels of the first color may be larger than the light-emitting elements in the sub-pixels of the second and third colors.

The display panel may further include a first pixel line along a row direction of the display panel; and a second pixel line along the row direction of the display panel and adjacent to the first pixel line. The first pixel line may include the first sub-pixel of the first color, the first sub-pixel of the second color, and the first sub-pixel of the third color. The second pixel line may include the second sub-pixel of the first color, the second sub-pixel of the second color, and the second sub-pixel of the third color.

The display panel may further include a gate line connected to the first sub-pixel of the first color, the second sub-pixel of the first color, the first sub-pixel of the second color, the second sub-pixel of the second color, the first sub-pixel of the second color, the first sub-pixel of the third color, and the second sub-pixel of the third color. The gate line may be connected in parallel to an output terminal of the gate driving circuit.

The display panel may further include a first-first data line intersecting the gate line and supplying a first-first data voltage to the first sub-pixel of the first color; a first-second data line intersecting the gate line and supplying a first-second data voltage to the second sub-pixel of the first color; a second-first data line intersecting the gate line and supplying a second-first data voltage to the first sub-pixel of the second color; a second-second data line intersecting the gate line and supplying a second-second data voltage to the second sub-pixel of the second color; a third-first data line intersecting the gate line and supplying a third-first data voltage to the first sub-pixel of the third color; and a third-second data line intersecting the gate line and supplying a third-second data voltage to the second sub-pixel of the third color.

The display panel may further include a first data line intersecting the gate line and supplying a first data voltage to the first sub-pixel of the first color and the second sub-pixel of the first color; a second data line intersecting the gate line and supplying a second data voltage to the first sub-pixel of the second color and the second sub-pixel of the second color; and a third data line intersecting the gate line and supplying a third data voltage to the first sub-pixel of the third color and the second sub-pixel of the third color.

The display panel may further include a first-first data line intersecting the gate line and supplying a first-first data voltage to the first sub-pixel of the first color; a first-second data line intersecting the gate line and supplying a first-second data voltage to the second sub-pixel of the first color; a second data line intersecting the gate line and supplying a second data voltage to the first sub-pixel of the second color and the second sub-pixel of the second color; and a third data line intersecting the gate line and supplying a third data voltage to the first sub-pixel of the third color and the second sub-pixel of the third color.

The display panel may further include a plurality of wires parallel to the row direction of the display panel. The plurality of wires may be between the first pixel line and the second pixel line. The plurality of wires may include one or more gate lines connected to the gate driving circuit; and a wire connected to a control node of the gate driving circuit.

A display panel according to one or more other embodiments of the present disclosure includes: a plurality of pixel areas including a plurality of pixels; and a gate driving area including a plurality of gate driving circuits that supply a gate signal to a plurality of gate lines connected to the plurality of pixels. The gate driving area is between adjacent pixel areas of the plurality of pixel areas. Each of the plurality of pixels includes: a first sub-pixel of a first color; a second sub-pixel of the first color that is adjacent to the first sub-pixel of the first color in a column direction of the display panel; a sub-pixel of a second color; and a sub-pixel of the third color that is adjacent to the sub-pixel of the second color in the column direction of the display panel. A length of a row direction of each of the first sub-pixel of the first color and the second sub-pixel of the first color is greater than a length of a row direction of each of the sub-pixel of the second color and the sub-pixel of the third color.

A display device according to one or more embodiments of the present disclosure includes: a plurality of display circuits combined on a plane. Each of the display circuits includes: the display panel; and a data driver configured to supply a data voltage to data lines on the display panel.

According to embodiments of the present disclosure, it is possible to implement a display panel which is advantageous for process optimization, high efficiency, high luminance, and long life by using a pixel structure which facilitates the improvement of the dark point.

The row direction length of the pixel may be reduced or minimized, thereby ensuring that the gate driving area in the display area is sufficiently secured.

The capacitance of the capacitor may be secured according to the driving characteristics of the light-emitting device chip for each color.

The wire resistance of the gate line may be reduced.

It is to be understood that both the foregoing general description and the following detailed description are exemplary and explanatory and are intended to provide further explanation of the inventive concepts as claimed.

The effects of the present disclosure are not limited to the above effects, and other effects not mentioned will obviously be understood by those skilled in the art from the following description and the appended claims.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principle of the disclosure. The above and other objects, features, and advantages of the present disclosure will become more apparent to those of ordinary skill in the art by describing embodiments thereof in detail with reference to the attached drawings, in which:

FIG. 1 is a block diagram schematically illustrating a configuration of a display device according to one or more embodiments of the present disclosure;

FIG. 2 is a partial cross-sectional view illustrating a pad and a side wiring disposed on the outer periphery of a display panel according to one or more embodiments of the present disclosure;

FIG. 3 is a perspective view illustrating a tiled display device according to one or more embodiments of the present disclosure;

FIG. 4 is a plan view schematically illustrating a planar structure of a display panel according to one or more embodiments of the present disclosure;

FIG. 5A is a circuit diagram illustrating a pixel circuit according to an embodiment of the present disclosure;

FIG. 5B is a circuit diagram illustrating a pixel circuit according to another embodiment of the present disclosure;

FIG. 6 is a block diagram schematically illustrating a gate driver according to one or more embodiments of the present disclosure;

FIG. 7 is a plan view schematically illustrating an example structure of a pixel according to one or more embodiments of the present disclosure.

FIG. 8 is a plan view illustrating wires connected to the pixel illustrated in FIG. 7 according to a first embodiment of the present disclosure;

FIG. 9 is a plan view illustrating wires connected to the pixel illustrated in FIG. 7 according to a second embodiment of the present disclosure;

FIG. 10 is a plan view illustrating wires connected to the pixel shown in FIG. 7 according to a third embodiment of the present disclosure;

FIG. 11 is a plan view illustrating an example of the wires disposed between the pixel lines shown in FIG. 7 according to one or more embodiments of the present disclosure;

FIG. 12 is a plan view schematically illustrating another example structure of a pixel according to one or more embodiments of the present disclosure;

FIG. 13 is a plan view illustrating wires connected to the pixel illustrated in FIG. 12 according to a first embodiment of the present disclosure;

FIG. 14 is a plan view illustrating wires connected to the pixel illustrated in FIG. 12 according to a second embodiment of the present disclosure; and

FIG. 15 is a plan view illustrating an example of the wires disposed between the pixel lines illustrated in FIG. 12 according to one or more embodiments of the present disclosure.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

Reference will now be made in detail to embodiments of the present disclosure, examples of which may be illustrated in the accompanying drawings. The progression of processing steps and/or operations described is an example; however, the sequence of steps and/or operations is not limited to that set forth herein and may be changed as is known in the art, with the exception of steps and/or operations necessarily occurring in a particular order. Names of the respective elements used in the following explanations may be selected only for convenience of writing the disclosure and may be thus different from those used in actual products.

The advantages and features of the present disclosure and methods for accomplishing the same will be more clearly understood from embodiments described below with reference to the accompanying drawings. However, the present disclosure is not limited to the following embodiments, but may be implemented in various different forms; rather, the present embodiments will make the disclosure of the present disclosure complete and allow those skilled in the art to fully comprehend the scope of the present disclosure.

In describing the present disclosure, detailed descriptions of known related technologies may be omitted so as not to unnecessarily obscure the subject matter of the present disclosure. Any implementation described herein as an “example” is not necessarily to be construed as preferred or advantageous over other implementations. In construing an element, the element is construed as including an error range or tolerance range although there is no explicit description of such an error or tolerance range.

The terms such as “comprising”, “including”, and “having” used herein are generally intended to allow other components to be added unless the terms are used with the term “only”. References to the singular shall be construed to include the plural unless expressly stated otherwise.

When describing a positional or interconnected relationship between two components, such as “on top of”, “above”, “below”, “next to”, “connect or couple with”, “crossing”, “intersecting” etc., one or more other components may be interposed between them unless “immediately” or “directly” is used.

The terms, such as “below,” “lower,” “above,” “upper” and the like, may be used herein to describe a relationship between item(s) as illustrated in the drawings. It will be understood that the terms are spatially relative and based on the orientation depicted in the drawings.

When describing a temporal contextual relationship is described, such as “after”, “following”, “next to” or “before”, it may not be continuous on a time scale unless “immediately” or “directly” is used.

The terms “first”, “second” “A,” “B,” “(a),” and “(b),” and the like may be used to distinguish components from each other, but the functions or structures of the components are not limited by ordinal numbers or component names in front of the components.

The term “at least one” should be understood as including any and all combinations of one or more of the associated listed items. For example, the meaning of “at least one of a first element, a second element, and a third element” compasses the combination of all three listed elements, combinations of any two of the three elements, as well as each individual element, the first element, the second element, or the third element.

The following embodiments may be combined or associated with each other in whole or in part, and various types of interlocking and driving are technically possible. The embodiments may be implemented independently of each other or together in an interrelated relationship.

A transistor is a three-electrode element including a gate, a source, and a drain. The source is an electrode that supplies carriers to the transistor. In the transistor, carriers start to flow from the source. The drain is an electrode through which carriers exit from the transistor. In a transistor, carriers flow from a source to a drain. In the case of an n-channel transistor, since carriers are electrons, a source voltage is a voltage lower than a drain voltage such that electrons may flow from a source to a drain. The n-channel transistor has a direction of a current flowing from the drain to the source. In the case of a p-channel transistor (p-channel metal-oxide semiconductor (PMOS)), since carriers are holes, a source voltage is higher than a drain voltage such that holes may flow from a source to a drain. In the p-channel transistor, since holes flow from the source to the drain, current flows from the source to the drain. It should be noted that a source and a drain of a transistor are not fixed. For example, a source and a drain may be changed according to an applied voltage. Therefore, the present disclosure is not limited to a source and a drain of a transistor. In the following description, a source and a drain of a transistor will be referred to as a first electrode and a second electrode.

A gate signal may swing between a gate-on voltage and a gate-off voltage. A transistor is turned on in response to a gate-on voltage and is turned off in response to a gate-off voltage. In the case of an n-channel transistor, the gate-on voltage may be a gate high voltage VGH, and the gate-off voltage may be a gate low voltage VGL. In the case of a p-channel transistor, the gate-on voltage may be the gate low voltage VGL, and the gate-off voltage may be the gate high voltage VGH.

A ‘line’ mentioned in embodiments of the present disclosure may be interpreted as a wire to which a signal or a voltage is applied.

Terms used in the embodiments of the present disclosure (including technical and scientific terms) are to be construed as they would be commonly understood by one of ordinary skill in the art to which the invention belongs, unless otherwise specifically defined and described, and commonly used terms, such as dictionary defined terms, are to be construed in light of their contextual meaning in the relevant art.

Hereinafter, preferred embodiments of the present disclosure will be described in detail with reference to the accompanying drawings.

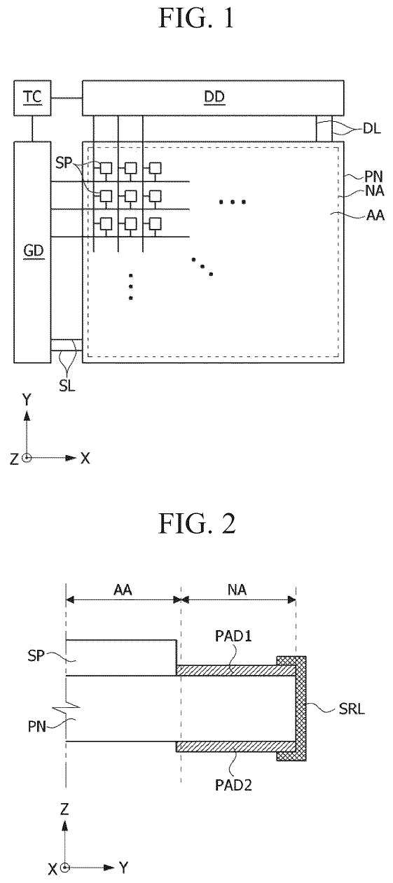

Referring to FIG. 1, a display device includes a display panel PN having a plurality of pixels disposed in a display area AA, and a display panel driving circuit for driving the pixels.

The display panel PN may be, but is not limited to, a panel having a rectangular structure with a length in the X-axis direction, a width in the Y-axis direction, and a thickness in the Z-axis direction. Embodiments of the present disclosure are however not limited thereto. As an example, the panel PN may have a rectangular structure with a length in the Y-axis direction, a width in the X-axis. As an example, the panel PN may have various structures such as a square structure, a curved structure, a circular structure, an oval structure, a rectangular structure with rounded corners, etc., other than the rectangular structure. The pixels include a plurality of sub-pixels SP with different colors. The display area AA on which an input image is displayed on the display panel PN may be a screen visible from the front surface of the display panel PN.

The display panel driving circuit includes a data driver DD, a gate driver GD, and a timing controller TC that controls the gate driver GD and the data driver DD, without being limited thereto. As an example, more components could be further included.

The input image is displayed on the sub-pixels SP disposed in the display area AA of the display panel PN. Each of the sub-pixels SP includes a light-emitting element and the pixel circuit that drives the light-emitting element. The light-emitting element may be a light-emitting diode (LED) or a micro light-emitting diode (micro-LED), or an organic light-emitting diode (OLED), without being limited thereto.

On the display panel PN, a plurality of gate lines SL and a plurality of data lines DL are arranged to cross each other. Each of the sub-pixels SP is connected to a gate line SL and a data line DL. Power wires omitted in FIG. 1 may be connected to the sub-pixels SP, respectively. In the display panel PN, a non-display area NA may be disposed outside the display area AA. As an example, the non-display area NA may extend from the display area AA. As an example, the non-display area NA may partially or fully surround the display area AA.

The gate driver GD supplies a gate signal to the gate lines SL in response to a gate control signal provided by the timing controller TC. The gate driver GD may be disposed at least in the non-display area NA of the display panel PN, as shown in FIG. 1, or in the display area AA. Embodiments are not limited thereto. As an example, the gate driver GD may be disposed in the non-display area NA in the form of a gate in panel (GIP). As an example, the gate driver GD may be separately provided (for example, on a separate panel), and then connected to the display panel PN in a tape automated bonding (TAB) method, a chip on glass (COG) method, a chip on panel (COP) method, or a chip on film (COF) method, without being limited thereto.

The data driver DD converts the image data received from the timing controller TC into a gamma compensation voltage in response to a data control signal provided by the timing controller TC and outputs a data voltage. The data voltage output from the data drive DD is fed to the data lines DL.

The timing controller TC aligns image data input from the outside and supplies the aligned image data to the data driver DD. The timing controller TC may generate gate control signals and data control signals based on timing signals synchronized with input image signals, for example, dot clock signals, data enable signals, and/or horizontal/vertical synchronization signals, without being limited thereto. The timing controller TC supplies the gate control signals to the gate driver GD and the data control signals to the data driver DD to control the timing of the operation of the gate driver GD and data driver DD.

The non-display area NA may have a link wire and a pad electrode disposed therein to transmit signals to the sub-pixels SP in the display area AA. One or more of a gate driver IC in which a circuit of the gate driver GD is integrated and a data driver IC in which a circuit of the data driver DD is integrated may be disposed in the non-display area NA, without being limited thereto. The non-display area NA may include the rear surface of the display panel PN, i.e., the rear surface without sub-pixels SP, without being limited thereto. As an example, the non-display area NA may not include the rear surface of the display panel PN. As an example, at least a portion of the non-display area NA may be bent toward the rear surface of the display panel PN. As an example, at least a portion of the non-display area NA may be bent to the rear surface of the display panel PN, so as to be not visible from the front surface of the display panel PN. As an example, the non-display area NA may be reduced or minimized so that it is partially or fully not visible when the image is displayed on the display panel PN.

The display panel driving circuit may be connected to the display panel PN in a variety of ways. For example, the gate driver GD may be disposed by a gate in panel (GIP) method in the non-display area NA, or by a gate in active area (GIA) method between the sub-pixels SP in the display area AA, without being limited thereto. The data driver DD and the timing controller TC may be formed on a separate flexible film and/or PCB, and the data driver DD and the timing controller TC may be electrically connected to the display panel PN by bonding the terminals of the flexible film to the pad electrode formed on the non-display area NA of the display panel PN. The flexible film bonded to the display panel PN may be connected to a PCB on which the circuit elements are mounted and the wires are formed.

As an example, a side wiring for connecting a signal wire on the front surface of the display panel PN to the pad electrode on the rear surface of the display panel PN may be formed on the side surface of the outer periphery of the display panel PN, without being limited thereto. Such a method of electrical connection between the front surface and the rear surface of the display panel PN via the side wiring may be used to maximally reduce or minimize the non-display area NA visible on the front surface of the display panel PN. In FIG. 2, “SRL” denotes this side wiring. When the gate driver GD, the data driver DD, and the timing controller TC are electrically connected to the display panel PN as described above, it is possible to substantially realize a screen without a bezel on the display panel PN.

Referring to FIG. 2, a plurality of pad electrodes are disposed in the non-display area NA of the display panel PN to transmit various signals to the sub-pixels SP. For example, a first pad electrode PAD1, which transmits signals to the sub-pixels SP, may be disposed in the non-display area NA located at the front surface of the display panel PN. A second pad electrode PAD2, which is electrically connected to circuit components such as the flexible film and the PCB, is disposed in the non-display area NA at the rear surface of the display panel PN. However, embodiments of the present disclosure are not limited thereto. As an example, the second pad electrode PAD2 may be disposed at the rear surface of the display panel PN in an area corresponding to either of the display area AA and the non-display area NA. Only the pad area in which the first pad electrode PAD1 is located is arranged in the non-display area NA located at the front outer periphery of the display panel PN in which an image is displayed, thereby reducing or minimizing the size of the non-display area.

Various signal wires connected to the sub-pixels SP, such as gate line SL or the data line DL, may extend into the non-display area NA and be electrically connected to the first pad electrode PAD1.

The display panel PN may include the side wiring SRL which is disposed on the side surface of the outer periphery of the display panel PN. The side wiring SRL may electrically connect the first pad electrode PAD1 disposed on the front outer periphery of the display panel PN and the second pad electrode PAD2 disposed on the rear (e.g., the rear outer periphery) of the display panel PN while traversing the side surface of the display panel PN. The signals output from the circuit components disposed on the rear surface of the display panel PN may be transmitted to the sub-pixels SP and the gate driver GD within the display area AA through the second pad electrode PAD2, the side wiring SRL, and the first pad electrode PAD1. Accordingly, a signal transmission path traversing the front, side, and rear surfaces may be formed at the outer periphery of the display panel PN, thereby reducing or minimizing the area of the non-display area NA on the front surface of the display panel PN.

Multiple display modules (e.g., display circuits) may be combined on one plane to implement a wide-screen tiled display device. Each of the display modules may be implemented as a single display device, and a combination of multiple display modules may be implemented as a wide-screen tiled display device. Each of the display modules includes a single sheet of a display panel PN, a driving circuit of the display panel PN, and cover members of the circuit components and modules coupled to the rear surface of the display panel PN.

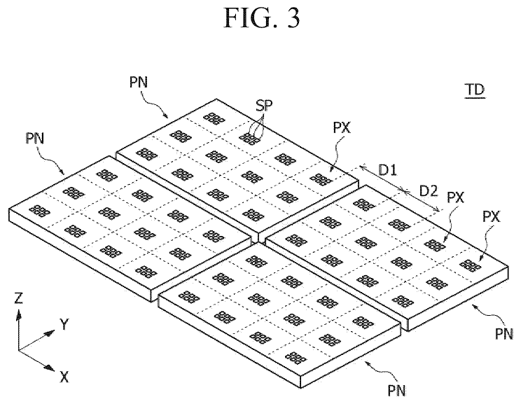

Referring to FIG. 3, a wide-screen tiled display TD includes a plurality of display modules disposed on an X-Y plane. Each of the display modules includes a display panel PN on which an input image is reproduced. When the non-display area NA is reduced or minimized at the front outer periphery of each display panel PN, a wide-screen image may be reproduced with no visible seams between adjacent display panels PN.

The display panels PN may be assembled on a plane such that the space D1 between the outermost pixel PX of one display panel PN and the outermost pixel PX of another display panel PN adjacent to the one display panel PN is substantially the same as the space D2 between adjacent pixels PX within the one display panel PN. As a result, the spaces D1 and D2 between the adjacent pixels PX is the same throughout the wide-screen display area of the tiled display TD, and thus the seam area is not visible.

In the tiled display TD, multiple display modules may share one timing controller TC, without being limited thereto. As an example, all of the display modules may share one timing controller TC. As an example, at least some of the display modules may share one timing controller TC. As an example, each of the display modules of the tiled display TD may have its own timing controller TC. As an example, the timing controllers TC of the display modules of the tiled display TD may be synchronized or not synchronized. As an example, a host system may be connected to a plurality of timing controllers TC, may transmit to the timing controllers TC image signals to be reproduced on all of the display panels PN implementing the wide-screen of the tiled display TD, and may synchronize the timing controllers TC.

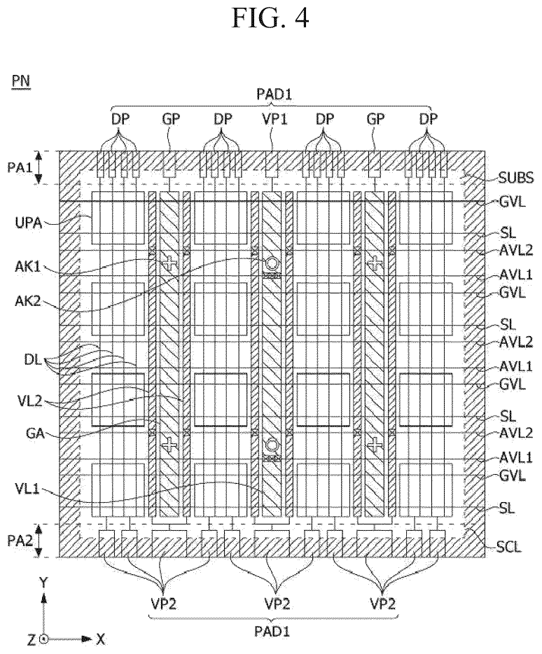

FIG. 4 is a plan view schematically illustrating a planar structure of a display panel according to one or more embodiments of the present disclosure.

Referring to FIG. 4, a display panel PN includes a substrate SUBS on which a pixel array and a circuit of a gate driver GD are disposed. The display panel 100 may be, but is not limited to, a panel having a rectangular structure with a length in the row direction (X-axis direction), a width in the column direction (Y-axis direction), and a thickness in the thickness direction (Z-axis direction).

The substrate SUBS may be an insulating substrate that supports components disposed on the upper portion of a display device. The substrate SUBS may be a single substrate or a stacked structure of multiple substrates. The substrate SUBS may be made of glass, polymer resin, or plastic substrate, without being limited thereto.

On one surface (or front surface) of the substrate SUBS, the display area AA may include a plurality of pixel areas UPA, a plurality of gate driving areas GA, and a plurality of pad areas PA1, PA2. One or more pixels PX may be disposed in each of the pixel areas UPA. The pixel areas UPA may be arranged along a plurality of row lines and a plurality of column lines. Each of the pixels PX include a plurality of sub-pixels SP with different colors. Each of the sub-pixels SP may include a light-emitting element and a pixel circuit, and emit light independently. The sub-pixels SP may include, but are not limited to, red sub-pixels, blue sub-pixels, and green sub-pixels. Embodiments are not limited thereto. As an example, at least some of the plurality of sub-pixels SP in one pixel PX may have the same color. As an example, at least some of the plurality of sub-pixels SP in one pixel PX may emit light dependently, and/or may share at least a portion of the pixel circuit. As an example, the sub-pixels SP may include a while sub-pixel, and sub-pixels of other colors such as Cyan, Magenta, Yellow, etc.

The plurality of gate driving areas GA includes circuits of gate drivers GD. The gate driving areas GA may be formed along a row direction and/or a column direction between the plurality of pixel areas UPA. A gate driver GD formed in a gate driving area GA may provide a gate signal to a plurality of gate lines SL. As an example, the gate driving area GA may be disposed between adjacent pixel areas UPD in the row direction (X-axis direction), without being limited thereto.

A first pad area PA1 includes a plurality of first pad electrodes PAD1 disposed on the front outer periphery of one side (or upper side) of the display panel PN. The first pad electrodes PAD1 may transmit various signals to various wires extending in the column direction from the display area AA. The first pad electrodes PAD1 include data pads DP connected to data lines DL for transmitting a data voltage from the data driver DD to the data lines DL, and gate pads GP connected to the gate driver GD for transmitting a clock signal, start signal, gate-low voltage, gate-high voltage, etc. to the gate driver GD. The clock signal, start signal, gate-low voltage, gate-high voltage, etc. for driving the gate driver GD may be generated from the timing controller TC and applied to the gate pads GP via a level shifter and a PCB, without being limited thereto. The first pad electrodes PAD1 may include a plurality of power wires to which a direct current voltage (or a constant voltage) is applied.

The substrate SUBS of the display panel PN includes gate driving wires GVL connected to the gate pads GP and extending in the column direction and a plurality of gate driving wires GVL extending in the row direction. The gate driving wires in the column direction and the gate driving wires GVL in the row direction may be connected through contact holes penetrating an insulating film. The gate driving wires GVL delivery signals necessary to drive the gate drivers GD distributed and disposed in the gate driving area GA, such as the clock signal, start signals, gate-high voltages, gate-low voltages, etc. to the circuits of the gate drives GD.

A second pad area PA2 includes a plurality of second pad electrodes PAD2 disposed on the front outer periphery of the other side (or lower side) of the display panel PN. The second pad area PA2 may include a plurality of low-potential power pads VP2.

A DC voltage to be applied to the power wires may be output from a power supply circuit omitted in the drawings, and may be applied to the power pads VP1 and VP2 connected to the power wires through the PCB. The power supply circuit may be a DC-DC converter disposed on the PCB or control boards arranged on the rear surface of the display panel PN to convert a DC input voltage from a main power source to a DC voltage suitable for driving the display panel PN.

The power pads VP1 and VP2 connected to the power wires may include a plurality of high-potential power supply pads VP1 disposed on the first pad area PA1 for supplying a high-potential power voltage to a high-potential power supply wires VL1, and a plurality of low-potential power supply pads VP2 disposed on the second pad area PA2 for supplying a low-potential power voltage to a low-potential power supply wire VL2.

The data pads DP, which are connected one-to-one to the data lines DL, may have a relatively narrow width, while the power pads VP1 and VP2 and the gate pads GP may have a relatively wide width. The low-potential power pads VP2 may have a wider width compared to the high-potential power pads VP2. Embodiments are not limited thereto. As an example, the data pads DP, the power pads VP1 and VP2 and the gate pads GP may have the same width, or may have various widths.

In order to reduce or minimize the outermost non-display area NA of the display panel PN, the pixel array, the wires, and the pads are formed on the front surface of the substrate of the display panel PN, and then the outermost periphery at the outside of a scribing line SCL indicated by a dotted line may be removed to provide the substrate SUBS with a reduced or minimized non-display area NA. After the scribing process, the rough edges of the outer periphery of the substrate SUBS may be ground or laser trimmed. This will leave the short pad electrodes PAD1 and PAD2 with a reduced size on the front outer periphery of the substrate SUBS.

The data lines DL may extend in the column direction (Y-direction) on the first substrate SUBS and overlap the pixel areas UPA. The data lines DL supply the data voltages to the respective pixel circuits of the sub-pixels SP. The gate lines SL may extend in the row direction (X-direction) on the substrate SUBS of the display panel PN and overlap the pixel areas UPA and the gate driving areas GA. The gate lines SL may supply the gate signals from the gate driver GD to the respective pixel circuits of the sub-pixels SP across the pixel areas UPA and the gate driving areas GA.

The high-potential power wires VL1 extend in the column direction (Y-direction), and at least one of them is connected in a mesh structure to auxiliary high-potential power wires AVL1 extending in the row direction (X-direction). The auxiliary high-potential power wires AVL1 are connected to the sub-pixels SP arranged in the row direction (X-direction). Therefore, the high-potential power voltage applied to the high-potential power wires VL1 may be supplied to the sub-pixels SP through the auxiliary high-potential power wires AVL1.

The low-potential power wires VL2 may extend in the column direction (Y-direction), and at least one of them may be connected in a mesh structure to auxiliary low-potential power wires AVL2 extending in the row direction (X-direction). The auxiliary low-potential power wires AVL2 are connected to the sub-pixels SP arranged in the row direction (X-direction). Therefore, the sub-pixels SP are connected to the auxiliary high-potential power wires AVL1 to which the low-potential power voltage is applied.

The mesh structure of the power wires may allow the resistance of the power wires to be reduced, which may improve the voltage drop of the high-potential power voltage and/or the low-potential power voltage and the deviation of the power voltage within the display area AA.

The substrate SUBS of the display panel PN may have one or more alignment keys AK1 and AK2 arranged between the pixel areas UPA. The alignment keys AK1 and AK2 may be used for alignment in the manufacturing process of the display panel PN. A first alignment key AK1 may be disposed in the gate driving area GA. The first alignment key AK1 may be used to check the aligned position of each of the light-emitting elements. The first alignment key AK1 may be formed in a cross pattern, but is not limited thereto. A second alignment key AK2 may overlap the high-potential power wires VL1. The high-potential power wires VL1 may include a hole formed in a position overlapping the second alignment key AK2, so that the second alignment key AK2 and the high-potential power wires VL1 may be distinguished. The second alignment key AK2 may be used to align the display panel PN with a donor substrate. The donor substrate is an intermediate medium for mounting the light-emitting elements on the substrate SUBS of the display panel PN. A plurality of light-emitting elements fabricated on a semiconductor wafer may be attached to and transferred to the donor substrate, and the light-emitting elements attached to the donor substrate may be transferred onto the substrate SUBS. The second alignment key AK2 may be formed in a circular or ring pattern, but is not limited to that.

Each of the sub-pixels SP includes a pixel circuit that drives the light-emitting element.

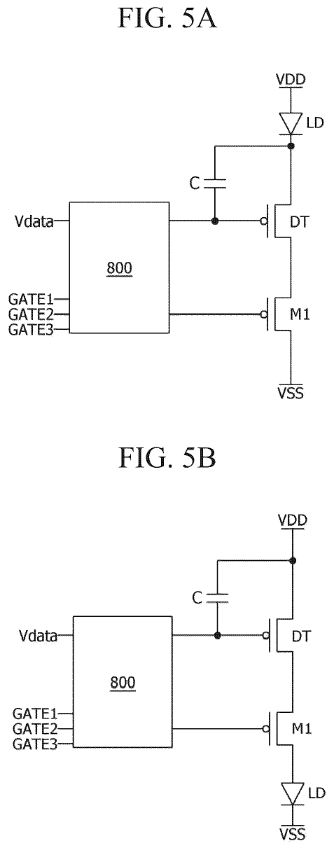

FIG. 5A is a circuit diagram illustrating a pixel circuit according to an embodiment of the present disclosure. FIG. 5B is a circuit diagram illustrating a pixel circuit according to another embodiment of the present disclosure.

Referring to FIGS. 5A and 5B, the pixel circuit includes a light-emitting element LD, a driving element DT, a switch element M1, and a compensation circuit 800. The driving element DT and the switch element M1 may be implemented as n-channel transistors, without being limited thereto. As an example, the driving element DT and the switch element M1 may be implemented as either of a n-channel transistor and a p-channel transistor. As an example, the driving element DT and the switch element M1 may be implemented as transistors of the same type or of different types. In FIGS. 5A and 5B, an example in which the driving element DT and the switch element M1 are implemented as p-channel transistors is illustrated, but is not limited thereto.

The light-emitting element LD may be a LED or a micro-LED. The light-emitting element LD includes an anode electrode and a cathode electrode. The light-emitting element LD may have, but is not limited to, a vertical structure in which electrodes are disposed above and below a chip in which the light-emitting element is integrated. As an example, the light-emitting element LD may be also implemented in a lateral structure or a flip chip structure, without being limited thereto.

The light-emitting element LD, the driving element DT, and the switch element M1 may be connected in series between a pixel driving voltage VDD and a cathode voltage VSS.

The driving element DT regulates the current flowing through a drain-to-source channel based on a gate-to-source voltage thereof. The gate-to-source voltage of the driving element DT is varied depending on a data voltage Vdata of the pixel data applied to a gate electrode of the driving element DT. Therefore, the current flowing through the driving element DT is varied depending on the data voltage Vdata. The light-emitting element LD may be driven by a current from the driving element DT to emit light. A capacitor C may be connected between the gate electrode and a first electrode of the driving element DT. The capacitor C is charged with the gate-source voltage Vgs of the driving element DT.

The driving element DT may be connected between the light-emitting element LD and the switch element M1, as shown in FIG. 5A. In this case, the driving element DT includes a gate electrode to which the data voltage Vdata is applied, a first electrode connected to a cathode electrode of the light-emitting element LD, and a second electrode connected to the switch element M1.

The driving element DT may be connected between a node to which the pixel driving voltage VDD is applied and the switch element M1, as shown in FIG. 5B. In this case, the driving element DT includes a gate electrode to which the data voltage Vdata is applied, a first electrode to which the pixel driving voltage VDD is applied, and a second electrode connected to the switch element M1.

The switch element M1 switches a current path between the pixel driving voltage VDD and the cathode voltage VSS under the control of the compensation circuit 800. The switch element M1 may be turned on in response to a gate-on voltage of one of the gate signals GATE1, GATE2, and GATE3, and turned off in response to a gate-off voltage. When the switch element M1 is turned on, the driving element DT and the light-emitting element LD may be electrically connected so that a current is supplied to the light-emitting element LD. When the switch element M1 is turned off, the current path between the pixel driving voltage VDD and the cathode voltage VSS is blocked so that no current is supplied to the light-emitting element LD.

The switch element M1 may be connected between the driving element DT and the cathode voltage VSS, as shown in FIG. 5A. In this case, the switch element M1 includes a gate electrode connected to a gate line to which one of the gate signals GATE1, GATE2, and GATE3 is applied, a first electrode connected to the second electrode of the driving element DT, and a second electrode connected to a node to which the cathode voltage VSS is applied.

The switch element M1 may be connected between the driving element DT and the light-emitting element LD, as shown in FIG. 5B. In this case, the switch element M1 includes a gate electrode connected to the gate line to which one of the gate signals GATE1, GATE2, and GATE3 is applied, a first electrode connected to the second electrode of the driving element DT, and a second electrode connected to the anode electrode of the light-emitting element LD.

The pixel driving voltage VDD and the cathode voltage VSS are applied to all of the pixels PX within the display panel PN. For example, the pixel driving voltage VDD may be applied to the pixels PX through a first power line connected to all of the pixels PX, and the cathode voltage VSS may be applied to the pixels PX through a second power line connected to all of the pixels PX. Meanwhile, a third constant voltage, for example a reference voltage, may be applied commonly to all or some of the pixels through a third power line, without being limited thereto. As an example, the third constant voltage may be omitted depending on the design.

The compensation circuit 800 is connected to the data line to which the data voltage Vdata is applied, the gate line to which one or more gate signals GATE1, GATE2, and GATE3 are applied, the gate electrode of the driving element DT, and the gate electrode of the switch element M1. The compensation circuit 800 uses a plurality of transistors to supply the data voltage Vdata to the gate electrode of the driving element DT. The compensation circuit 800 samples the threshold voltage of the driving element DT to the capacitor C to compensate the gate voltage of the driving element DT by the amount of the threshold voltage of the driving element DT. The compensation circuit 800 may compensate for the threshold voltage of the driving element DT using a source follower or a diode connection circuit.

As an example, the gate driver GD sequentially outputs the gate signals GATE1, GATE2 and GATE3 under the control of the timing controller TC, without being limited thereto. The gate driver GD may sequentially shift pulses of the gate signals GATE1, GATE2, and GATE3 using one or more shift registers. As an example, the gate driver GD may include a first shift register that sequentially outputs a first gate signal GATE1, a second shift register that sequentially outputs a second gate signal GATE2, and a third shift register that sequentially outputs a third gate signal GATE3. The first gate signal GATE1 may be interpreted as a first scan signal, the second gate signal GATE2 may be interpreted as a second scan signal, and the third gate signal GATE3 may be interpreted as an emission signal, but are not limited thereto. As an example, at least one of the gate signals GATE1, GATE2, and GATE3 could be omitted depending on the design.

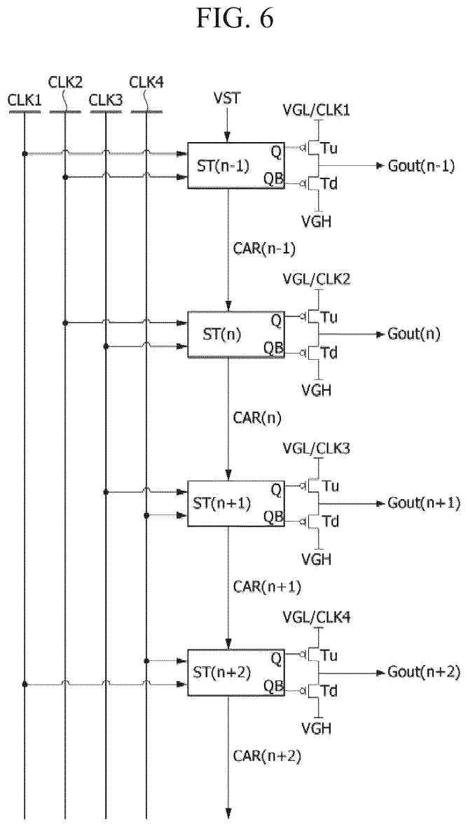

FIG. 6 is a block diagram schematically illustrating the gate driver GD according to one or more embodiments of the present disclosure.

Referring to FIG. 6, the shift register in the gate driver GD includes signal transmission parts [ST(n−1) to St (n+2)] connected in cascade.

The signal transmission parts [ST(n−1) to ST(n+2)] are connected to clock wires to which clocks CLK1 and CLK4 are applied. The signal transmission parts [ST(n−1) to ST(n+2)] are connected in cascade by carry signal wires to which carry pulses [CAR(n−1) to CAR(n+2)] are applied. The clocks CLK1 to CLK4 may be shown as 4-phase clocks in FIG. 6, but are not limited thereto. For example, an i-phase (where i is a natural number greater than or equal to 2) may be input in the shift register.

Each of the signal transmission parts [ST(n−1) to ST(n+2)] may include a VST node to which a start pulse VST or a carry pulse is input, CLK nodes to which shift clocks CLK1 to CLK4 is input, a first output node from which a pulse of gate signals [Gout(n−1) to Gout(n+2)] is output, and a second output node from which a pulse of carry pulses [CAR(n−1) to CAR(n+2)] is output. The first output node, from which the gate pulse is output, is connected to the gate line of the display panel. As an example, the gate pulses [Gout(n−1) to Gout(n+2)] and the carry pulses [CAR(n−1) to CAR(n+2)] may be output through a common output node. In this case, the second output node and the first output node may be connected to the one common output node. However, embodiments of the present disclosure are not limited thereto. As an example, the gate pulses [Gout(n−1) to Gout(n+2)] and the carry pulses [CAR(n−1) to CAR(n+2)] may be output through separate output nodes.

The start pulse VST is generally input to a first signal transmission part. In an example of FIG. 6, an (n−1)th signal transmission part [ST(n−1)] may be the first signal transmission part. The signal transmission parts [ST(n) to ST(n+2)] connected in cascade to the (n−1)th signal transmission part [ST(n−1)] are started to be driven upon receiving the pulse of the carry signals [CAR(n−1) to CAR(n+2)] as the start pulse from their respective preceding signal transmission parts. The signal transmitters [ST(n−1) to ST(n+2)] may output the pulse of the carry signals [CAR(n−1) to CAR(n+2)] through their second output nodes while outputting the pulse of the gate signals [Gout(n−1) to Gout(n+2)] through their first output nodes, respectively.

Each of the signal transmission parts [ST(n−1) to ST(n+2)] includes a first control node Q, a second control node QB, and a buffer circuit. Each of the signal transmission parts [ST(n−1) to ST(n+2)] may charge and discharge the first and second control nodes Q and QB using a plurality of transistors. As an example, a reset pulse from a next signal transmission part may be input to a reset node of the signal transmission parts [ST(n−1) to ST(n+2)], without being limited thereto. The signal transmission parts [ST(n−1) to ST(n+2)] may discharge the first control node Q in response to the reset pulse from the next signal transmission parts.

The buffer circuit outputs the pulse of the gate signal through a pull-up transistor Tu and a pull-down transistor Td to a gate line connected to the pixel circuit through the first output node or the common output node.

When the shift clocks CLK1 to CLK4 are input while the first control node Q has been charged, the buffer circuit may supply the gate-on voltage VGL or the shift clocks CLK1 to CLK4 to the first output node or the common output node, thereby causing the gate signals [Gout(n−1) to Gout(n+2)] to rise up to the gate-on voltage VGL. The buffer circuit may discharge the first output node or the common output node to invert the voltage of the gate signal to the gate-off voltage VGH when the second control node QB is charged. Although is illustrated that the gate-on voltage is the gate-low voltage VGL, and the gate-off voltage is the gate-high voltage VGH, embodiments are not limited thereto. As an example, the gate-on voltage may be the gate-high voltage VGH, and the gate-off voltage may be the gate-low voltage VGL.

The pull-up transistor Tu includes a gate electrode connected to the first control node Q, a CLK node to which the shift clocks CLK1 to CLK4 is input or a first electrode to which the gate-on voltage VGL is applied, and a second electrode connected to the first output node or the common output node. The pull-down transistor Td includes a gate electrode connected to the second control node QB, a first electrode connected to the first output node or the common output node, and a second electrode to which the gate-off voltage VGH is applied.

An inverter circuit, which is omitted in FIG. 6, may be connected between the first control node Q and the second control node QB. The inverter circuit controls the voltages of the first control node Q and the second control node QB to ensure that the voltages are inverted.

The circuit of the gate driver GD may be disposed within the display area AA of the display panel PN as shown in FIG. 4. In this case, the circuit of the gate driver GD may be disposed in the gate driving area GA between the adjacent pixel areas UPA. As shown in FIG. 3, it is advantageous to reduce the space D2 between the pixels PX within the display panel PN and reduce the distance in the row direction (X-axis direction) of the pixel area UPA to secure the gate driving area GA.

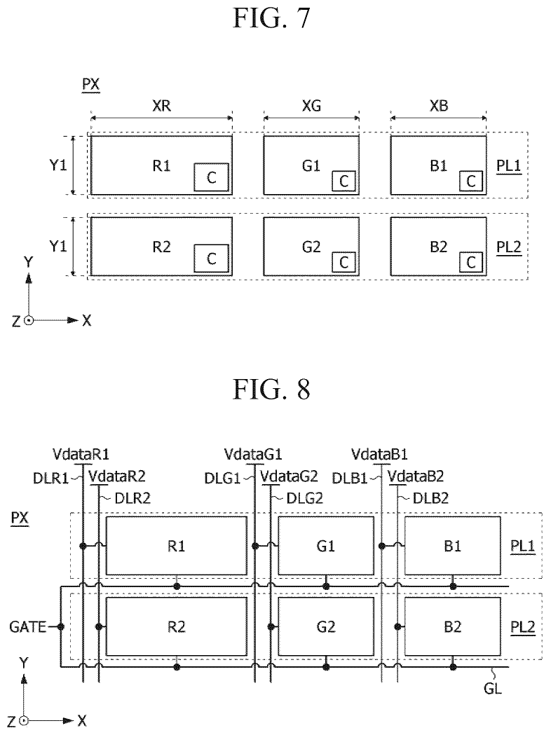

FIG. 7 is a plan view schematically illustrating an example structure of the pixel PX according to one or more embodiments of the present disclosure. In the display area AA of the display panel PN, a unit pixel PX shown in FIG. 7 may be repeated along the row direction (X-axis direction) and the column direction (Y-axis direction).

Referring to FIG. 7, the pixel PX includes a first sub-pixel R1 of a first color, a second sub-pixel R2 of the first color, a first sub-pixel G1 of a second color, a second sub-pixel G2 of the second color, a first sub-pixel B1 of a third color, and a second sub-pixel B2 of the third color. Although it is illustrated that the first sub-pixel and the second sub-pixel of the same color are arranged in the Y-axis direction, and the first sub-pixel of different colors are arranged in the X-axis direction, embodiments are not limited thereto. As an example, the first sub-pixel and the second sub-pixel of the same color may be arranged in the X-axis direction or a direction other than the X-axis direction and the Y-axis direction, and the first sub-pixel of different colors may be arranged in the Y-axis direction or a direction other than the X-axis direction and the Y-axis direction.

When two sub-pixels for each color are arranged in the unit pixel PX, it is advantageous to improve the dark point. For example, if either of the two sub-pixels R1 and R2 of the first color is found to be defective, a repair process is performed to turn the defective sub-pixel into a dark point and to increase the luminance of the other sub-pixel of the first color, so that the corresponding pixel PX may be driven normally. As an example, an optical compensation method may be used to adjust the luminance of a sub-pixel. For example, the compensation circuit within the timing controller TC may compensate for the luminance of a sub-pixel having turned into a dark point (the defective sub-pixel) by adding or multiplying the luminance compensation value to the pixel data to be written to the other sub-pixel of the same color. The compensation circuit may compensate for luminance on a sub-pixel basis using a look-up table in which a predetermined compensation value is registered for each sub-pixel.

The first color, the second color, and the third color may be red, green, and blue, respectively, without being limited thereto. To reduce the length of the pixel PX in the row direction (X-axis direction), as an example, the first and second sub-pixels for each color may be disposed along the column direction (Y-axis direction), without being limited thereto. As an example, the luminous efficiency of the light-emitting element of the first color may not be as good as the light-emitting element of the second and third colors. In consideration of this, the light-emitting element of the first color may be implemented as a larger light-emitting element chip than the light-emitting element of the second and third colors, without being limited thereto. In order to increase the amount of current for driving the light-emitting elements of the first color, the driving elements may be larger than the driving elements disposed in the sub-pixels of the second and third colors. Therefore, the sub-pixels R1 and R2 of the first color may be larger than the sub-pixels G1, G2, B1, and B2 of the second and third colors because they have the larger driving elements for compensating the luminous efficiency. Embodiments are not limited thereto. As an example, one of the light-emitting element of the second color and the light-emitting element of the third color may be implemented as a larger light-emitting element chip than the other. As an example, the light-emitting element of the first color, the light-emitting element of the second color and the light-emitting element of the third color may be implemented as light-emitting element chips of the same size.

The first and second sub-pixels R1 and R2 of the first color are disposed adjacent to each other in the column direction (Y-axis direction). The first sub-pixel R1 of the first color may be disposed on a first pixel line PL1. The second sub-pixel R2 of the first color may be disposed on a second pixel line PL2 below the first pixel line PL1. The first sub-pixel G1 of the second color is disposed on the first pixel line PL1 so that it is adjacent to the first sub-pixel R1 of the first color in the row direction (X-axis direction). The second sub-pixel G2 of the second color may be disposed on the second pixel line PL2 so that it is adjacent to the first sub-pixel G1 of the second color in the column direction (Y-axis direction). The first and second sub-pixels G1 and G2) of the second color are adjacent in the column direction (Y-axis direction).

The first sub-pixel B1 of the third color is disposed on the first pixel line PL1 so that it is adjacent to the first sub-pixel G1 of the second color in the row direction (X-axis direction). The second sub-pixel B2 of the third color is disposed on the second pixel line PL2 so that it is adjacent to the first sub-pixel B1 of the third color in the column direction (Y-axis direction). The first and second sub-pixels B1 and B2 of the third color are adjacent in the column direction (Y-axis direction).

The sub-pixels R1 and R2 of the first color may be larger than the sub-pixels G1, G2, B1, and B2 of the second and third colors due to the relatively large light-emitting element LD of the first color. A row direction length XR of each of the first and second sub-pixels R1 and R2 of the first color is greater than a row direction length XG and XB of each of the sub-pixels G1, G2, B1, and B2 of the second and third colors. A column-direction length Y1 of each of the first and second sub-pixels R1 and R2 of the first color is substantially the same as a column-direction length of each of the sub-pixels G1, G2, B1, and B2 of the second and third colors. Embodiments are not limited thereto. As an example, the column-direction length Y1 of each of the first and second sub-pixels R1 and R2 of the first color may be also greater than a column-direction length of each of the sub-pixels G1, G2, B1, and B2 of the second and third colors, without being limited thereto.

The row direction lengths XG and XB of each of the sub-pixels G1, G2, B1, and B2 of the second and third colors may be substantially equal to each other, without being limited thereto. The column direction lengths of each of the sub-pixels G1, G2, B1, and B2 of the second and third colors may be substantially the same.

The current and voltage required to drive the light-emitting element that emits the first color of light, the light-emitting element that emits the second color of light, and the light-emitting element that emits the third color of light may vary according to the chip characteristics. For example, red light-emitting device chips require greater current and voltage than blue and green light-emitting device chips. As shown in FIG. 7, the sub-pixels of the first color that require a relatively large current and voltage may have a capacitor C having a larger capacity than the sub-pixels of the other colors, without being limited thereto. Accordingly, the capacity of the capacitor may be secured according to the driving characteristics of the light-emitting element chip of each color.

Since two sub-pixels for each color are disposed along the column direction (Y-axis direction), the length of the pixel PX may be smaller in the row direction. As a result, the one or more embodiments may effectively respond to the dark point defects by arranging two sub-pixels for each color, as well as reduce or minimize the length of the pixel PX in the row direction to secure the gate driving area GA.

FIG. 8 is a plan view illustrating wires connected to the pixel illustrated in FIG. 7 according to a first embodiment of the present disclosure.

Referring to FIG. 8, the sub-pixels R1 and R2, G1, G2, B1, and B2 of the first, second, and third colors share a gate line GL. In other words, the gate line GL to which a gate signal GATE is applied is commonly connected to the sub-pixels R1 and R2, G1, G2, B1, and B2 disposed on the first and second pixel lines PL1 and PL2. Thus, the gate signal GATE is applied simultaneously to the sub-pixels R1 and R2, G1, G2, B1, and B2 disposed on the two pixel lines PL1 and PL2.

Two neighboring gate lines GL may be connected to one output terminal of the gate driver GD in parallel and is commonly connected to the sub-pixels R1 and R2, G1, G2, B1, and B2 disposed on the adjacent pixel lines PL1 and PL2. Accordingly, the wire resistance of the gate line GL may be reduced.

When a plurality of gate signals are applied to each of the sub-pixels R1 and R2, G1, G2, B1, and B2, each of the gate lines to which the plurality of gate signals are applied respectively is commonly connected to the sub-pixels R1 and R2, G1, G2, B1, and B2 on the first and second pixel lines PL1 and PL2. For example, a first gate line to which a first gate signal GATE1 is applied may be commonly connected to the sub-pixels R1 and R2, G1, G2, B1, and B2, and a second gate line to which a second gate signal GATE2 is applied may be commonly connected to the sub-pixels R1 and R2, G1, G2, B1, and B2. Further, a third gate line to which a third gate signal GATE3 is applied may be commonly connected to the sub-pixels R1 and R2, G1, G2, B1, and B2.

The data driver DD converts the pixel data received from the timing controller TC to data voltages suitable for driving the sub-pixels. The data driver DD may convert pixel data of the first color to be written in the first sub-pixel R1 of the first color and pixel data of the first color to be written in the second sub-pixel R2 of the first color into the first-first and first-second data voltages VdataR1 and VdataR2, respectively, and output the converted voltages. The data driver DD may convert pixel data of the second color to be written in the first sub-pixel G1 of the second color and pixel data of the second color to be written in the second sub-pixel G2 of the second color into second-first and second-second data voltages VdataG1 and VdataG2, respectively, and output the converted voltages. The data driver DD may convert pixel data of the third color to be written in the first sub-pixel B1 of the third color and pixel data of the third color to be written in the second sub-pixel B2 of the third color into third-first and third-second data voltages VdataB1 and VdataB2, respectively, and output the converted voltages.

Data lines DLR1 to DLB2 intersect with the gate line GL. The data lines DLR1 to DLB2 may be connected independently for each sub-pixel. The first sub-pixel R1 of the first color is connected to a first-first data line DLR1 to charge the first-first data voltage VdataR1 supplied through the first-first data line DLR1. The second sub-pixel R2 of the first color is connected to a first-second data line DLR2 to charge the first-second data voltage VdataR2 supplied through the first-second data line DLR2. Since the first-first and first-second sub-pixels R1 and R2 may share the gate line GL, they may charge the data voltages VdataR1 and VdataR2 simultaneously. Since the data lines DLR1 and DLR2 connected to the first and second sub-pixels R1 and R2 of the first color are separated, the first and second sub-pixels R1 and R2 may charge the different data voltages VdataR1 and VdataR2 to emit light at different luminance, or at the same luminance.

The first sub-pixel G1 of the second color is connected to a second-first data line DLG1 to charge the second-first data voltage VdataG1 supplied through the second-first data line DLG1. The second sub-pixel G2 of the second color is connected to a second-second data line DLG2 to charge the second-second data voltage VdataG2 supplied through the second-second data line DLG2. Since the second-first and second-second sub-pixels G1 and G2 may share the gate line GL, they may charge the data voltages VdataG1 and VdataG2 simultaneously. Since the data lines DLG1 and DLG2 connected to the first and second sub-pixels G1 and G2 of the second color are separated, the first and second sub-pixels G1 and G2 may charge the different data voltages VdataG1 and VdataG2 to emit light at different luminance, or at the same luminance.

The first sub-pixel B1 of the third color is connected to a third-first data line DLB1 to charge the third-first data voltage VdataB1 supplied through the third-first data line DLB1. The second sub-pixel B2 of the third color is connected to a third-second data line DLB2 to charge the third-second data voltage VdataB2 supplied through the third-second data line DLB2. Since the third-first and third-second sub-pixels B1 and B2 may share the gate line GL, they may charge the data voltages VdataB1 and VdataB2 simultaneously. Since the data lines DLB1 and DLB2 connected to the first and second sub-pixels B1 and B2 of the third color are separated, the first and second sub-pixels B1 and B2 may charge the different data voltages VdataB1 and VdataB2 to emit light at different luminance, or at the same luminance.

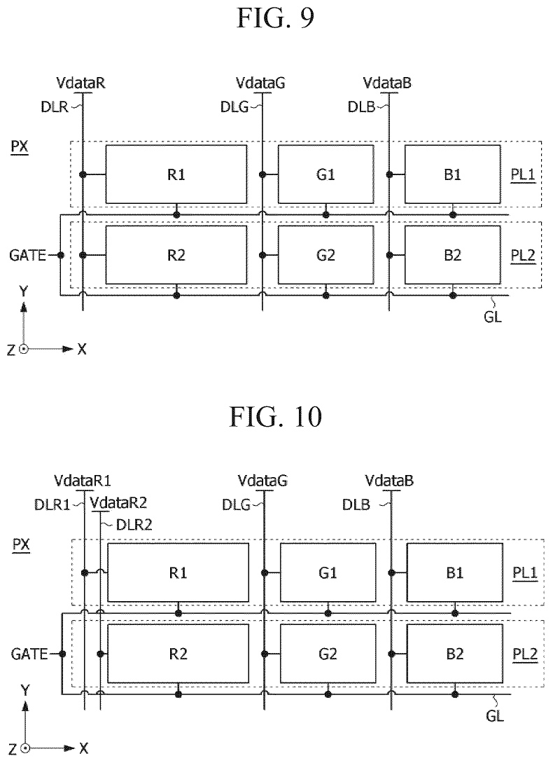

FIG. 9 is a plan view diagram illustrating wires connected to the pixel illustrated in FIG. 7 according to a second embodiment of the present disclosure.

Referring to FIG. 9, the sub-pixels R1 and R2, G1, G2, B1, and B2 of the first, second, and third colors share the gate line GL. Data lines DLR, DLG, and DLB may be commonly connected to the sub-pixels of the same color and separated between the sub-pixels of different colors.

The first and second sub-pixels R1 and R2 of the first color are connected to a first data line DLR to simultaneously charge a first data voltage VdataR supplied through the first data line DLR.

The first and second sub-pixels G1 and G2 of the second color are connected to a second data line DLG to simultaneously charge the second data voltage VdataG supplied through the second data line DLG. The first and second sub-pixels B1 and B2 of the third color are connected to a third data line DLB to simultaneously charge the third data voltage VdataB supplied through the third data line DLB.

FIG. 10 is a plan view illustrating wires connected to the pixel illustrated in FIG. 7 according to a third embodiment of the present disclosure.

Referring to FIG. 10, the sub-pixels R1 and R2, G1, G2, B1, and B2 of the first, second, and third colors share the gate line GL. Thus, the gate signal GATE is applied simultaneously to the sub-pixels R1 and R2, G1, G2, B1, and B2 disposed on the two pixel lines PL1 and PL2.

The first sub-pixel R1 of the first color is connected to a first-first data line DLR1 to charge the first-first data voltage VdataR1 supplied through the first-first data line DLR1. The second sub-pixel R2 of the first color is connected to a first-second data line DLR2 to charge a first-second data voltage VdataR2 supplied through a first-second data line DLR2. Since the first-first and first-second sub-pixels R1 and R2 may share the gate line GL, they may charge the data voltages VdataR1 and VdataR2 simultaneously. Since the data lines DLR1 and DLR2 connected to the first and second sub-pixels R1 and R2 of the first color are separated, the first and second sub-pixels R1 and R2 may charge the different data voltages VdataR1 and VdataR2 to emit light at different luminance or at the same luminance.

The first and second sub-pixels G1 and G2 of the second color are connected to a second data line DLG to simultaneously charge the second data voltage VdataG supplied through the second data line DLG. The first and second sub-pixels B1 and B2 of the third color are connected to a third data line DLB to simultaneously charge the third data voltage VdataB supplied through the third data line DLB.

The light-emitting elements of the first color may have a large difference in luminous efficiency from the light-emitting elements of the second and third colors. In this case, the first and second sub-pixels R1 and R2 of the first color need to emit light at different luminance to optimize the white luminance and color coordinates of the pixel. For example, when the sub-pixels of the second and third colors G1, G2, B1, and B2 are emitted at 50% luminance, the first sub-pixel R1 of the first color needs to be emitted at 50% luminance and the second sub-pixel R2 of the first color at 75% luminance. In the pixel illustrated in FIG. 10, the luminance of the sub-pixels R1 and R2 of the first color may be controlled independently. On the other hand, the sub-pixels G1 and G2 of the second color may be emitted at almost the same luminance because the same data voltage is applied, and the sub-pixels B1 and B2 of the third color may also be emitted at the same luminance.

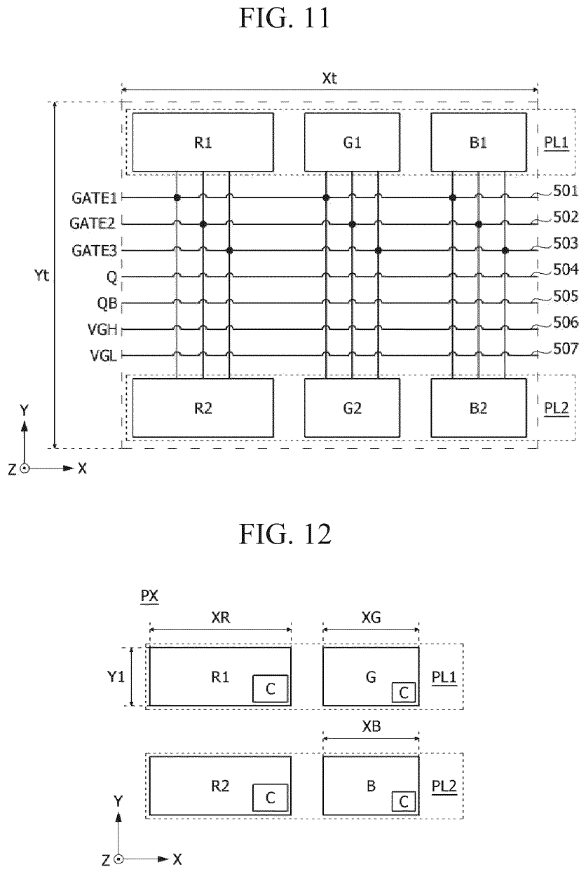

FIG. 11 is a plan view illustrating an example of the wires disposed between the pixel lines shown in FIG. 7 according to one or more embodiments of the present disclosure. In FIG. 11, “Xt” and “Yt” denote the lengths in the row direction (X-axis direction) and column direction (Y-axis direction) of a unit pixel, respectively. The pixel PX shown in FIGS. 7 to 10 may have a reduced row direction length Xt.

Referring to FIG. 11, gate lines 501, 502, and 503 to which gate signals GATE1, GATE2, and GATE3 are applied and wires 504, 505, 506, and 507 connected to the gate driver GD may be disposed between the pixel lines PL1 and PL2. Each of the gate lines 501, 502, and 503 is commonly connected to the sub-pixels R1 and R2, G1, G2, B1, and B2 of the unit pixel.

The circuit of the gate driver GD may be separately disposed in the gate driving areas GA spaced apart from each other with one or more pixels PX interposed therebetween. In this case, the wires 504, 505, 506, and 507 connected to the gate driver GD in the gate driving areas GA may cross the pixel PX along the row direction (X-axis direction) between the pixel lines PL1 and PL2 and may be connected to the gate driver GD of another adjacent gate driving area GA. These wires 504, 505, 506, and 507 may include one or more of a wire 504 connected to the first control node Q, a wire 505 connected to the second control node QB, a wire 506 to which the gate-off voltage VGH is applied, and a wire 507 to which the gate-on voltage VGL is applied.

FIG. 12 is a plan view schematically illustrating another example structure of the pixel PX according to one or more embodiments of the present disclosure. In the display area AA of the display panel PN, a unit pixel PX shown in FIG. 12 may be repeated along the row direction (X-axis direction) and the column direction (Y-axis direction).

Referring to FIG. 12, the pixel PX includes a first sub-pixel R1 of a first color, a second sub-pixel R2 of the first color, a sub-pixel G of a second color, and a sub-pixel B of a third color.

The first color, the second color, and the third color may be red, green, and blue, respectively, without being limited thereto. Sub-pixels of other colors may be additionally or alternatively included. To reduce the length of the pixel PX in the row direction (X-axis direction), the first and second sub-pixels R1 and R2 of the first color are arranged along the column direction (Y-axis direction) so that they are adjacent in the column direction (Y-axis direction). The sub-pixels G and B of the second and third colors are arranged along the column direction (Y-axis direction) and are adjacent in the column direction (Y-axis direction).

The first sub-pixel R1 of the first color and the sub-pixel G of the second color may be disposed on the first pixel line PL1. The second sub-pixel R2 of the first color and the sub-pixel B of the third color may be disposed on the second pixel line PL2 below the first pixel line PL1.

The sub-pixels R1 and R2 of the first color may be larger than the sub-pixels G and B of the second and third colors due to the relatively large light-emitting element LD of the first color. The row direction length XR of each of the first and second sub-pixels R1 and R2 of the first color is greater than the row direction lengths XG and XB of each of the sub-pixels G and B of the second and third colors. The column direction length Y1 of each of the first and second sub-pixels R1 and R2 of the first color is substantially equal to the column direction length of each of the sub-pixels G and B of the second and third colors.

The row direction lengths XG and XB of each of the sub-pixels G and B of the second and third colors may be substantially equal to each other, without being limited thereto. As an example, the row direction lengths XG and XB of each of the sub-pixels G and B of the second and third colors may be different from each other. The column direction length of each of the sub-pixels G and B of the second and third colors may be substantially the same.

The light-emitting elements that emit light of the first color may require higher currents and voltages than the light-emitting elements that emit light of other colors. To this end, the capacitors C disposed in the relatively large first color sub-pixels R1 and R2 may be larger than the capacitors C formed in the other color sub-pixels G and B.

Since the pixel PX shown in FIG. 12 has a small length in the row direction (X-axis direction), it may be possible to sufficiently secure the gate driving area GA to be disposed between the pixel areas UPA.

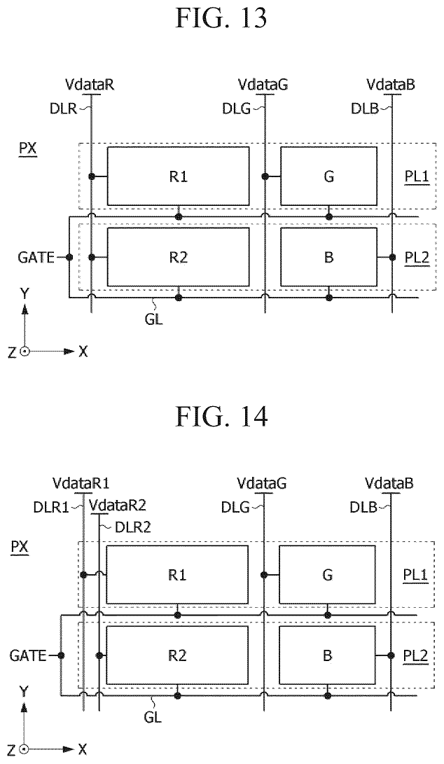

FIG. 13 is a plan view illustrating wires connected to the pixel illustrated in FIG. 12 according to a first embodiment of the present disclosure.

Referring to FIG. 13, the sub-pixels R1, R2, G, and B of the first, second, and third colors share the gate line GL. Thus, the gate signal GATE is applied simultaneously to the sub-pixels R1 R2, G, and B disposed on the two pixel lines PL1 and PL2.

When a plurality of gate signals are applied to each of the sub-pixels R1, R2, G, and B, each of the gate lines to which the plurality of gate signals are applied respectively is commonly connected to the sub-pixels R1, R2, G, and B on the first and second pixel lines PL1 and PL2. For example, a first gate line to which the first gate signal GATE1 is applied may be commonly connected to the sub-pixels R1, R2, G, and B, and a second gate line to which the second gate signal GATE2 is applied may be commonly connected to the sub-pixels R1, R2, G, and B. Further, a third gate line to which a third gate signal GATE3 is applied may be commonly connected to the sub-pixels R1, R2, G, and B.

The first and second sub-pixels R1 and R2 of the first color are connected to the first data line DLR to simultaneously charge the first data voltage VdataR supplied through the first data line DLR.

The sub-pixel G of the second color is connected to a second data line DLG to charge the second data voltage VdataG supplied through the second data line DLG. The sub-pixel B of the third color is connected to the third data line DLB to charge the third data voltage VdataB supplied through the third data line DLB.

FIG. 14 is a plan view diagram illustrating wires connected to the pixel illustrated in FIG. 12 according to a second embodiment of the present disclosure.

Referring to FIG. 14, the sub-pixels R1, R2, G, and B of the first, second, and third colors share the gate line GL. Thus, the gate signal GATE is applied simultaneously to the sub-pixels R1 R2, G, and B disposed on the two pixel lines PL1 and PL2.

The first sub-pixel R1 of the first color is connected to a first-first data line DLR1 to charge the first-first data voltage VdataR1 supplied through the first-first data line DLR1. The second sub-pixel R2 of the first color is connected to a first-second data line DLR2 to charge the first-second data voltage VdataR2 supplied through the first-second data line DLR2. Since the first-first and first-second sub-pixels R1 and R2 may share the gate line GL, they may charge the data voltages VdataR1 and VdataR2 simultaneously. Since the data lines DLR1 and DLR2 connected to the first and second sub-pixels R1 and R2 of the first color are separated, the first and second sub-pixels R1 and R2 may charge the different data voltages VdataR1 and VdataR2 to emit light at different luminance or the same luminance.

The sub-pixel G of the second color is connected to the second data line DLG to charge the second data voltage VdataG supplied through the second data line DLG. The sub-pixel B of the third color is connected to the third data line DLB to charge the third data voltage VdataB supplied through the third data line DLB.

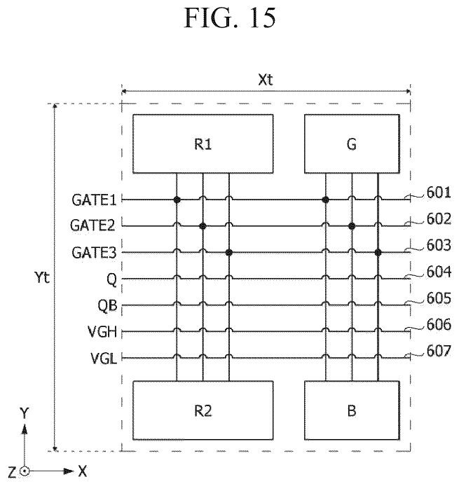

FIG. 15 is a plan view illustrating an example of the wires disposed between the pixel lines illustrated in FIG. 12 according to one or more embodiments of the present disclosure. In FIG. 15, “Xt” and “Yt” denote the lengths in the row direction (X-axis direction) and column direction (Y-axis direction) of a unit pixel, respectively. The pixel PX shown in FIGS. 12 to 14 may have a reduced row direction length Xt.

Referring to FIG. 15, gate lines 601, 602, and 603 to which gate signals GATE1, GATE2, and GATE3 are applied and wires 604, 605, 606, and 507 connected to the gate driver GD may be disposed between the pixel lines PL1 and PL2. Each of the gate lines 601, 602, and 603 is commonly connected to the sub-pixels R1 and R2, G, and B of the unit pixel.

The circuit of the gate driver GD may be separately disposed in the gate driving areas GA spaced apart from each other with one or more pixels PX interposed therebetween. In this case, the wires 504, 505, 506, and 507 connected to the gate driver GD in the gate driving areas GA may cross the pixel PX along the row direction (X-axis direction) between the pixel lines PL1 and PL2 and may be connected to the gate driver GD of another adjacent gate driving area GA. These wires 604, 605, 606, and 607 may include one or more of a wire 604 connected to the first control node Q, a wire 605 connected to the second control node QB, a wire 606 to which the gate-off voltage VGH is applied, and a wire 607 to which the gate-on voltage VGL is applied.

According to one or more embodiments of the present disclosure, the display device may be applied to mobile devices, video phones, smart watches, watch phones, wearable device, foldable device, rollable device, bendable device, flexible device, curved device, sliding device, variable device, electronic organizer, electronic books, portable multimedia players (PMPs), personal digital assistants (PDAs), MP3 players, mobile medical devices, desktop PCs, laptop PCs, netbook computers, workstations, navigations, vehicle navigations, vehicle display devices, vehicle devices, theater devices, theater display devices, televisions, wallpaper devices, signage devices, game devices, laptops, monitors, cameras, camcorders, and home appliances, etc. Additionally, the display device according to one or more embodiments of the present disclosure may be applied to organic light emitting lighting devices or inorganic light emitting lighting devices.

The objects to be achieved by the present disclosure, the means for achieving the objects, and effects of the present disclosure described above do not specify essential features of the claims, and thus, the scope of the claims is not limited to the disclosure of the present disclosure.

It will be apparent to those skilled in the art that various modifications and variations can be made in the display device of the present disclosure without departing from the technical idea or scope of the disclosure. Thus, it is intended that the present disclosure cover the modifications and variations of this disclosure provided they come within the scope of the appended claims and their equivalents.

What is claimed is:

1. A display panel, comprising:
a plurality of pixel areas including a plurality of pixels; and
a gate driving area including a plurality of gate driving circuits, the plurality of gate driving circuits supplying a gate signal to a plurality of gate lines that are connected to the plurality of pixels and extend along a row direction of the display panel, the gate driving area between adjacent pixel areas of the plurality of pixel areas,
wherein each of the plurality of pixels includes:
a first sub-pixel of a first color;
a second sub-pixel of the first color that is adjacent to the first sub-pixel of the first color in a column direction of the display panel;
a first sub-pixel of a second color;
a second sub-pixel of the second color that is adjacent to the first sub-pixel of the second color in the column direction of the display panel;
a first sub-pixel of a third color; and
a second sub-pixel of the third color that is adjacent to the first sub-pixel of the third color in the column direction of the display panel, and
wherein a length of a row direction of each of the first sub-pixel of the first color and the second sub-pixel of the first color is greater than a length of a row direction of each of the first sub-pixel of the second color and the second sub-pixel of the second color.

2. The display panel of claim 1, wherein the first color is red, the second color is green, and the third color is blue.

3. The display panel of claim 1, wherein each of the first sub-pixel of the first color, the second sub-pixel of the first color, the first sub-pixel of the second color, the second sub-pixel of the second color, the first sub-pixel of the third color, and the second sub-pixel of the third color includes:
a driving element configured to supply current to a light-emitting element; and
a capacitor connected to the driving element, and
wherein capacitors in the first sub-pixel of the first color and the second sub-pixel of the first color are larger than capacitors in the first sub-pixel of the second color, the second sub-pixel of the second color, the first sub-pixel of the third color and the second sub-pixel of the third color.

4. The display panel of claim 3, wherein light-emitting elements in the first sub-pixel of the first color and the second sub-pixel of the first color are larger than light-emitting elements in the first sub-pixel of the second color, the second sub-pixel of the second color, the first sub-pixel of the third color and the second sub-pixel of the third color.

5. The display panel of claim 1, further comprising:
a first pixel line along the row direction of the display panel; and
a second pixel line along the row direction of the display panel and adjacent to the first pixel line,
wherein the first pixel line includes the first sub-pixel of the first color, the first sub-pixel of the second color, and the first sub-pixel of the third color, and
wherein the second pixel line includes the second sub-pixel of the first color, the second sub-pixel of the second color, and the second sub-pixel of the third color.

6. The display panel of claim 5, further comprising:
a gate line connected to the first sub-pixel of the first color, the second sub-pixel of the first color, the first sub-pixel of the second color, the second sub-pixel of the second color, the first sub-pixel of the third color, and the second sub-pixel of the third color,
wherein an output terminal of a gate driving circuit of the plurality of gate driving circuits is connected in parallel to two neighboring gate lines.

7. The display panel of claim 6, further comprising:
a first-first data line intersecting the gate line, the first-first data line supplying a first-first data voltage to the first sub-pixel of the first color;
a first-second data line intersecting the gate line, the first-second data line supplying a first-second data voltage to the second sub-pixel of the first color;
a second-first data line intersecting the gate line, the second-first data line supplying a second-first data voltage to the first sub-pixel of the second color;
a second-second data line intersecting the gate line, the second-second data line supplying a second-second data voltage to the second sub-pixel of the second color;
a third-first data line intersecting the gate line, the third-first data line supplying a third-first data voltage to the first sub-pixel of the third color; and
a third-second data line intersecting the gate line, the third-second data line supplying a third-second data voltage to the second sub-pixel of the third color.

8. The display panel of claim 6, further comprising:
a first data line intersecting the gate line, the first data line supplying a first data voltage to the first sub-pixel of the first color and the second sub-pixel of the first color;
a second data line intersecting the gate line, the second data line supplying a second data voltage to the first sub-pixel of the second color and the second sub-pixel of the second color; and
a third data line intersecting the gate line, the third data line supplying a third data voltage to the first sub-pixel of the third color and the second sub-pixel of the third color.

9. The display panel of claim 6, further comprising:
a first-first data line intersecting the gate line, the first-first data line supplying a first-first data voltage to the first sub-pixel of the first color;
a first-second data line intersecting the gate line, the first-second data line supplying a first-second data voltage to the second sub-pixel of the first color;
a second data line intersecting the gate line, the second data line supplying a second data voltage to the first sub-pixel of the second color and the second sub-pixel of the second color; and
a third data line intersecting the gate line, the third data line supplying a third data voltage to the first sub-pixel of the third color and the second sub-pixel of the third color.

10. The display panel of claim 1, further comprising:
a first-first data line supplying a first-first data voltage to the first sub-pixel of the first color; and
a first-second data line supplying a first-second data voltage to the second sub-pixel of the first color,
wherein the first-first data voltage is equal to or different from the first-second data voltage.

11. The display panel of claim 5, further comprising:
a plurality of wires parallel to the row direction of the display panel,
wherein the plurality of wires are between the first pixel line and the second pixel line, and
wherein the plurality of wires include:
one or more gate lines connected to a gate driving circuit of the plurality of gate driving circuits; and
a wire connected to a control node of the gate driving circuit.

12. The display panel of claim 1, wherein the length of the row direction of each of the first sub-pixel of the first color and the second sub-pixel of the first color is greater than a length of a row direction of each of the first sub-pixel of the third color and the second sub-pixel of the third color.

13. The display panel of claim 12, wherein a length of a column-direction of each of the first sub-pixel of the first color and the second sub-pixel of the first color is a same as a length of a column-direction of the first sub-pixel of the second color, the second sub-pixel of the second color, the first sub-pixel of the third color and the second sub-pixel of the third color.

14. The display panel of claim 1, wherein the gate driving area is between adjacent pixel areas of the plurality of pixel areas in the row direction of the display panel.

15. The display panel of claim 1, wherein one of the first sub-pixel of the first color and the second sub-pixel of the first color is a dark point, and a luminance of another one of the first sub-pixel of the first color and the second sub-pixel of the first color is compensated by a timing controller of the display panel.

16. A display panel, comprising:
a plurality of pixel areas including a plurality of pixels; and
a gate driving area including a plurality of gate driving circuits, the plurality of gate driving circuits supplying a gate signal to a plurality of gate lines that are connected to the plurality of pixels and extend along a row direction of the display panel, the gate driving area between adjacent pixel areas of the plurality of pixel areas,
wherein each of the plurality of pixels includes:
a first sub-pixel of a first color;
a second sub-pixel of the first color that is adjacent to the first sub-pixel of the first color in a column direction of the display panel;
a sub-pixel of a second color; and
a sub-pixel of a third color that is adjacent to the sub-pixel of the second color in the column direction of the display panel, and
wherein a length of a row direction of each of the first sub-pixel of the first color and the second sub-pixel of the first color is greater than a length of a row direction of each of the sub-pixel of the second color and the sub-pixel of third color.

17. The display panel of claim 16, wherein each of the first sub-pixel of the first color, the second sub-pixel of the first color, the sub-pixel of the second color, and the sub-pixel of the third color includes:
a driving element configured to supply current to a light-emitting element; and
a capacitor connected to the driving element, and
wherein capacitors in the first sub-pixel of the first color and the second sub-pixel of the first color are larger than capacitors in the sub-pixel of the second color and the sub-pixel of third color.

18. The display panel of claim 17, wherein light-emitting elements in the first sub-pixel of the first color and the second sub-pixel of the first color are larger than light-emitting elements in the sub-pixel of the second color and the sub-pixel of third color.

19. The display panel of claim 16, further comprising:
a first pixel line along the row direction of the display panel; and
a second pixel line along the row direction of the display panel and adjacent to the first pixel line,
wherein the first pixel line includes the first sub-pixel of the first color and the sub-pixel of the second color, and
wherein the second pixel line includes the second sub-pixel of the first color and the sub-pixel of the third color.

20. The display panel of claim 19, further comprising:
a gate line connected to the first sub-pixel of the first color, the second sub-pixel of the first color, the sub-pixel of the second color, and the sub-pixel of the third color,
wherein the gate line is connected in parallel to an output terminal of a gate driving circuit of the plurality of gate driving circuits.

21. The display panel of claim 20, further comprising:
a first data line intersecting the gate line, the first data line supplying a first data voltage to the first sub-pixel of the first color and the second sub-pixel of the first color;
a second data line intersecting the gate line, the second data line supplying a second data voltage to the sub-pixel of the second color; and
a third data line intersecting the gate line, the third data line supplying a third data voltage to the sub-pixel of the third color.

22. The display panel of claim 20, further comprising:
a first-first data line intersecting the gate line, the first-first data line supplying a first-first data voltage to the first sub-pixel of the first color;
a first-second data line intersecting the gate line, the first-second data line supplying a first-second data voltage to the second sub-pixel of the first color;
a second data line intersecting the gate line, the second data line supplying a second data voltage to the sub-pixel of the second color; and
a third data line intersecting the gate line, the third data line supplying a third data voltage to the sub-pixel of the third color.

23. The display panel of claim 19, further comprising:
a plurality of wires parallel to the row direction of the display panel,
wherein the plurality of wires are between the first pixel line and the second pixel line, and
wherein the plurality of wires include:
one or more gate lines connected to a gate driving circuit of the plurality of gate driving circuits; and
a wire connected to a control node of the gate driving circuit.

24. A display device comprising:
a plurality of display circuits combined on a plane,
wherein each of the plurality of display circuits includes the display panel according to claim 1.

25. The display device of claim 24, wherein a space in a row direction of the display device between a first outermost pixel of a first display panel of the display device and a second outermost pixel of a second display panel of the display device that is adjacent to the first display panel in the row direction of the display device is a same as a space between adjacent pixels of the first display panel in a row direction of the first display panel.
